(19) United States
(12) Patent Application Publication
(10) Pub. No.: US 2024/0306395 A1
(43) Pub. Date: Sep. 12, 2024

(54) FERROELECTRIC BASED MEMORY DEVICE AND MANUFACTURING METHOD OF THE SAME

(71) Applicant: KOREA UNIVERSITY RESEARCH AND BUSINESS FOUNDATION, Seoul (KR)

(72) Inventors: Hyun-Yong YU, Seoul (KR); Dong-Gyu JIN, Seoul (KR)

(73) Assignee: KOREA UNIVERSITY RESEARCH AND BUSINESS FOUNDATION, Seoul (KR)

(21) Appl. No.: 18/512,857

(22) Filed: Nov. 17, 2023

(30) Foreign Application Priority Data
Mar. 8, 2023 (KR) 10-2023-0030600

(51) Int. Cl. H10B 51/30; H01L 29/66; H01L 29/78; H01L 29/786

(52) U.S. Cl. CPC H10B 51/30; H01L 29/66969; H01L 29/78391; H01L 29/7869

(57) ABSTRACT

Disclosed are a ferroelectric-based semiconductor device and a method of manufacturing the same. The ferroelectric-based semiconductor device includes a substrate used as a gate; a gate oxide film formed on the substrate; a channel formed on the gate oxide film; and a source/drain formed on the channel, and the semiconductor device is plasma treated. The ferroelectric-based semiconductor device may be used as a memory device and an artificial synaptic device.

### CROSS-REFERENCE TO RELATED APPLICATION(S)

This application claims the benefit under 35 USC § 119(a) of Korean Patent Application No. 10-2023-0030600 filed on Mar. 8, 2023 in the Korean Intellectual Property Office, the entire disclosure of which is incorporated herein by reference for all purposes.

### BACKGROUND

### 1. Field

At least one example embodiment relates to a ferroelectric-based semiconductor, memory, and neuromorphic device that are in the spotlight as next-generation semiconductor devices, and technology for improving characteristics thereof.

### 2. Description of Related Art

A von Neumann architecture, a computing system that has been commercialized to date, uses a method of sequentially processing necessary operations. The von Neumann architecture has an advantage of being able to quickly process simple operations, but has a disadvantage of taking a long time and consuming high power when processing complex operations, such as object recognition and learning.

To overcome such limitations, a neuromorphic system capable of operating with low power and significantly reducing a processing time of complex operations through parallel processing has attracted considerable interest. The neuromorphic system mimics a human brain system to process operations and includes an artificial synapse and an artificial neuron. Here, the artificial synapse serves to process operations and store results at the same time and simultaneously performs functions of a processor and a memory used in the conventional von Neumann architecture. Therefore, a role of the artificial synapse may be most important in the neuromorphic system and an operation accuracy of the neuromorphic system may be determined according to an operating characteristic of the artificial synapse. The artificial synapse operates by controlling synaptic plasticity in response to an input signal. Here, linearity of the synaptic plasticity, the number of storage states, and a maximum/minimum state ratio may be measured as operating characteristics.

A ferroelectric-based memory and an artificial synaptic device classify a storage state using hysteresis of threshold voltage by polarization according to an input signal. Here, a hysteresis phenomenon by a polarization phenomenon needs to appear counterclockwise. However, an interface trap present between a ferroelectric and a channel causes counterclockwise threshold voltage hysteresis, which disrupts the polarization phenomenon of the ferroelectric. Therefore, since a memory window is reduced and synaptic characteristics are significantly degraded, research is required on the effect of interface trap and a method of reducing the same.

The present invention proposes technology for developing a ferroelectric-based memory and an artificial synaptic device, discovering that an interface trap is a factor impeding their characteristics, and improving memory and synaptic characteristics through interface trap reduction technology using plasma.

### SUMMARY

A technical subject of at least one example embodiment is to provide a ferroelectric-based semiconductor device and a neuromorphic device with improved device characteristics and a manufacturing method thereof.

According to an aspect of at least one example embodiment, there is provided a ferroelectric-based semiconductor device including a substrate used as a gate; a gate oxide film formed on the substrate; a channel formed on the gate oxide film; and a source/drain formed on the channel. The semiconductor device is plasma-treated.

Also, according to an aspect of at least one example embodiment, there is provided a method of manufacturing a ferroelectric-based semiconductor device, the method including preparing a substrate; depositing a gate oxide film on the substrate; forming a channel on the gate oxide film; forming a source/drain on the channel; and plasma-treating the semiconductor device.

According to some example embodiments, it is possible to provide a semiconductor device, a memory device, and an artificial synaptic device with improved device characteristics.

The aforementioned features and effects of the disclosure will be apparent from the following detailed description related to the accompanying drawings and accordingly those skilled in the art to which the disclosure pertains may easily implement the technical spirit of the disclosure.

### BRIEF DESCRIPTION OF THE DRAWINGS

These and/or other aspects, features, and advantages of the disclosure will become apparent and more readily appreciated from the following description of example embodiments, taken in conjunction with the accompanying drawings of which:

FIG. 1 illustrates a device and characteristics of the device according to an example embodiment;

FIG. 2 illustrates ferroelectric field-effect transistor (FeFET) devices with four different conditions of oxygen plasma treatments and current-voltage (I-V) characteristics of the FeFET devices;

FIG. 3 illustrates box plot of electrical characteristics of data extracted from transfer curve of FeFET devices;

FIG. 4 illustrates deconvoluted X-ray photoelectron spectroscopy (XPS) spectra of O 1s peak;

FIG. 5 illustrates an operation mechanism of fabricated FeFET; and

FIG. 6 illustrates measured synaptic plasticity of a FeFET-based artificial synaptic device.

### DETAILED DESCRIPTION

Disclosed hereinafter are exemplary embodiments of the present invention. Particular structural or functional descriptions provided for the embodiments hereafter are intended merely to describe embodiments according to the concept of the present invention. The embodiments are not limited as to a particular embodiment.

Various modifications and/or alterations may be made to the disclosure and the disclosure may include various example embodiments. Therefore, some example embodiments are illustrated as examples in the drawings and described in detailed description. However, they are merely intended for the purpose of describing the example embodiments described herein and may be implemented in various forms. Therefore, the example embodiments are not construed as limited to the disclosure and should be understood to include all changes, equivalents, and replacements within the idea and the technical scope of the disclosure.

Terms such as “first” and “second” may be used to describe various parts or elements, but the parts or elements should not be limited by the terms. The terms may be used to distinguish one element from another element. For instance, a first element may be designated as a second element, and vice versa, while not departing from the extent of rights according to the concepts of the present invention.

Unless otherwise clearly stated, when one element is described, for example, as being “connected” or “coupled” to another element, the elements should be construed as being directly or indirectly linked (i.e., there may be an intermediate element between the elements). Similar interpretation should apply to such relational terms as “between”, “neighboring,” and “adjacent to.”

Terms used herein are used to describe a particular exemplary embodiment and should not be intended to limit the present invention. Unless otherwise clearly stated, a singular term denotes and includes a plurality. Terms such as “including” and “having” also should not limit the present invention to the features, numbers, steps, operations, subparts and elements, and combinations thereof, as described; others may exist, be added or modified. Existence and addition as to one or more of features, numbers, steps, etc. should not be precluded.

Unless otherwise clearly stated, all of the terms used herein, including scientific or technical terms, have meanings which are ordinarily understood by a person skilled in the art. Terms, which are found and defined in an ordinary dictionary, should be interpreted in accordance with their usage in the art. Unless otherwise clearly defined herein, the terms are not interpreted in an ideal or overly formal manner.

Example embodiments of the present invention are described with reference to the accompanying drawings. However, the scope of the claims is not limited to or restricted by the example embodiments. Like reference numerals proposed in the respective drawings refer to like elements.

Currently, a neuromorphic computing system is proposed to overcome limitations of the conventional von Neumann computing system. The neuromorphic computing system may operate with low power and significantly reduce a processing time of complex operations through parallel processing. For a high-performance neuromorphic system, a ferroelectric field-effect transistor (FeFET)-based artificial synaptic device is required. A ferroelectric material exhibits spontaneous polarization characteristics, which may switch a polarization direction and may be maintained without an additional electrical input signal. Using this characteristic, conductance of a channel may be precisely controlled by applying an electrical input signal to a gate terminal to determine “0” or “1” state.

Various types of perovskite-based materials have been studied as ferroelectric materials, including PbZr₁₋ₓTiₓO₃, LiNbO₃, and BaTiO₃. However, such materials have low compatibility with a complementary metal-oxide-semiconductor (CMOS) manufacturing process and have difficulty in mass communication and complexity of the manufacturing process. Therefore, oxide-based ferroelectric materials have been studied. In particular, hafnium oxide-based materials, which are known to exhibit excellent ferroelectric characteristics, have been studied for use of ferroelectric layers in FeFETs. Hf_{0.5}Zr_{0.5}O₂ (HZO), which is zirconium-doped HfO₂ that exhibits high ferroelectricity at a thickness of a few nanometers and is highly compatible with the CMOS manufacturing process, has received wide interest. Also, an interfacial layer formed between ferroelectric and silicon layers during a post-annealing process deteriorates polarization switching characteristics, such as operation voltage and a memory window. However, hafnium oxide-based ferroelectric materials are significantly more immune to deterioration compared to perovskite-based ferroelectric materials.

An artificial synaptic device simultaneously performs information processing, such as output prediction, pattern recognition, and learning by regulating synaptic weight according to presynaptic signals, and storing the processed information and thus, is a core component of a neuromorphic system. That is, the artificial synaptic device simultaneously performs processor and memory operations. HZO-based FeFETs have been considered as candidates of the artificial synaptic device since the synaptic weight may be precisely controlled with polarization switching along a presynaptic signal and the controlled synaptic weight may be maintained for a long period of time. However, interface traps present at interface of a channel/ferroelectric layer degrade controllability of the synaptic weight. When an input voltage is applied to a gate terminal, polarization occurs inside the ferroelectric layer, shifting a threshold voltage in a negative direction. However, electrons in the channel are also trapped in interface traps, causing the threshold voltage to shift in a direction opposite to the direction in which the threshold voltage is shifted by polarization. Therefore, the interface trap density needs to be reduced to enhance ferroelectric and synaptic characteristics.

Herein, a 3-terminal artificial synaptic device based on an HZO ferroelectric layer is proposed to achieve a high-performance neuromorphic system. First, ferroelectric characteristics of the proposed FeFET were investigated by measuring remanent polarization (Pr) and by analyzing an X-ray diffraction (XRD) pattern. Electrical characteristics of a FET, including subthreshold swing (SS), an on/off current ratio, hysteresis of threshold voltage, and interface trap density, were investigated by inserting an HfO₂ insulating layer between a ferroelectric layer and an indium-gallium-zinc oxide (IGZO) channel layer to reduce gate leakage. Also, oxygen plasma treatment was performed to improve ferroelectric and electrical characteristics of the FeFET by reducing the interface trap density. The effect of the oxygen plasma treatment was confirmed using electrical and X-ray photoelectron spectroscopy (XPS) depth analysis. Finally, synaptic plasticity with outstanding synaptic characteristics, such as long-term plasticity (LTP), was exhibited through the reduced interface trap density using the oxygen plasma treatment. A potentiation/depression behavior was implemented with presynaptic pulses having a constant amplitude, and the linearity of a synaptic weight change, a ratio of maximum to minimum conductance, and the number of synaptic weights were measured. Overall, the artificial synaptic device exhibiting highly repeatable LTP and high performance was implemented using the HZO-based FeFET with oxygen plasma treatment.

Hereinafter, a method of manufacturing a synaptic device and/or a semiconductor device according to an example embodiment will be described.

A heavily doped p-type silicon wafer is prepared, and a cleaning process is performed using acetone, isopropanol, and deionized water. Here, the silicon wafer may be used as a gate.

75 nm of Hf_{0.5}Zr_{0.5}O₂ is deposited using a radio-frequency sputtering system under argon and oxygen atmospheres. That is, a ferroelectric layer (gate oxide film) is deposited (formed). Depending on example embodiments, an oxide ferroelectric, such as A₁:hfO₂, HfZrO, etc., an organic ferroelectric, such as P (VDF-TrFE), and a two-dimensional (2D) ferroelectric material, such as InSe, CIPS, etc., may be used as the ferroelectric layer. Also, after deposition or immediately after deposition, rapid thermal annealing (RTA) may be performed at 900° C., for 3 min under a vacuum condition.

In sequence, 20 nm of IGZO may be deposited by sputtering an IGZO target (In:Ga:Zn=1:1:1 mol %) under an argon and oxygen gas flow. Additionally, furnace annealing may be performed in an ambient atmosphere at 400° C., for 30 min to produce IGZO with high conductivity. Finally, Au/Ti/Au may be deposited using an E-beam evaporator at 20, 60, and 20 nm, respectively, to use the same as a source/drain.

For example, oxygen plasma treatment is performed using an inductively coupled plasma-reactive ion etching (ICPRI) device. Only source power is used to minimize the channel surface damage and varies from 100 to 500 W. A chamber pressure and an oxygen flow rate are fixed at 30 mTorr and 50 sccm, respectively. XPS depth analysis was used to investigate HfO₂/IGZO and Hf_{0.5}Zr_{0.5}O₂/HfO₂ interfaces by sputtering layers from the top of the device. Electrical data, such as transfer curve, potentiation/depression curve, and subthreshold swing, was measured with Keithley 4200A.

A semiconductor device manufactured through the aforementioned process may be used as a device, for example, a memory device, an artificial synaptic device, magneto-resistive random access memory (MRAM), ferroelectric random access memory (FeRAM)_, extended gate field effect transistor (EGFET), FET, and the like.

Hereinafter, results of performance measurement are described.

### 1. Electrical Characteristic and Ferroelectricity of FeFET

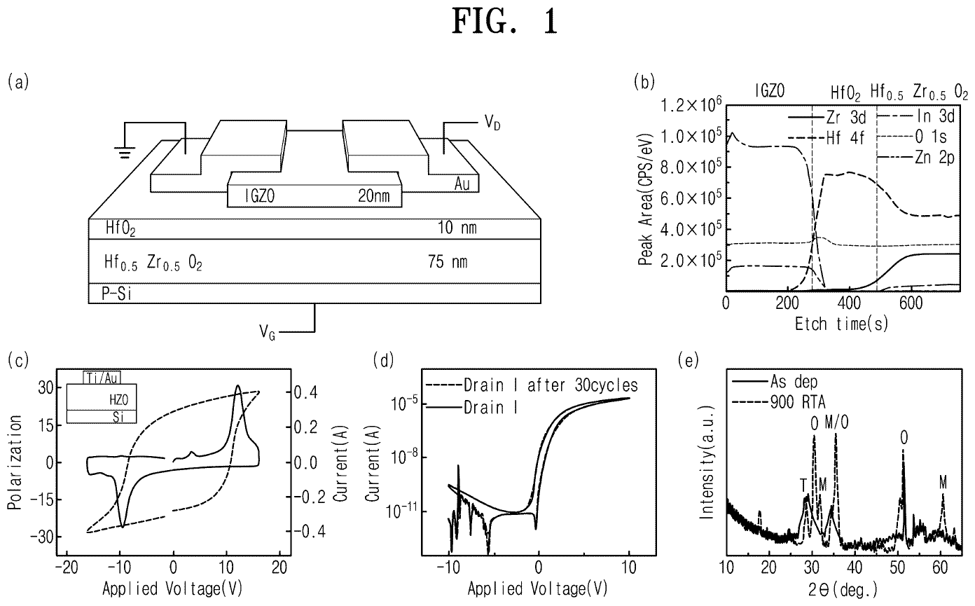

FIG. 1 illustrates a device and characteristics of the device according to an example embodiment. (a) of FIG. 1 illustrates a structure of an oxide ferroelectric material-based FeFET using a Si substrate as a gate terminal and using IGZO as a channel layer. (b) of FIG. 1 illustrates an XPS depth profile etched from the top of the FeFET device after annealing twice. A dashed line indicates an interface between the respective layers. (c) of FIG. 1 illustrates measured polarization-voltage curve (dashed line) and current-voltage curve (solid line). Here, 2Pᵣ is equal to 42.25. (d) of FIG. 1 illustrates transfer curve of the HZO-based FeFET. (e) of FIG. 1 illustrates XRD analysis showing HZO crystallinity. Dashed and solid lines represent the measured peak.

An oxide ferroelectric material based-3 terminal FeFET was fabricated. As illustrated in (a) of FIG. 1, highly doped Si was used as a gate terminal and an HZO layer was fabricated as a ferroelectric layer. Also, 20 nm thick IGZO was used as a channel layer. Also, an HfO₂ dielectric layer may be inserted between HZO and IGZO to improve electrical characteristics. A post-annealing process for ensuring the ferroelectricity of the ferroelectric layer may be performed. In this process, an interfacial layer that deteriorates the ferroelectricity may be formed between the gate and the ferroelectric layer and between the channel and the ferroelectric layer may be formed. To minimize deterioration of ferroelectricity, HZO is used as the ferroelectric layer. An interfacial layer between Si and hafnium-based ferroelectric oxide has a lower effect on the ferroelectricity than other perovskite-based ferroelectric materials. To reduce generation of the interfacial layer between the ferroelectric layer and the channel layer, oxide semiconductor IGZO was used as a channel material. Finally, the source/drain was formed with a gold contact. As illustrated in (b) of FIG. 1, structural stability is maintained using the XPS depth profile even after two annealing processes.

The ferroelectricity of p-Si/HZO/Au stack was investigated using the polarization-voltage (P-V) curve and current-voltage (I-V) curve ((c) of FIG. 1). When a positive voltage is applied to the gate terminal, polarization inside the HZO film occurs in a direction from metal to the gate terminal. Conversely, when a negative voltage is applied to the gate terminal, the polarization occurs in a direction from the gate terminal to the metal. Typical characteristics of the P-V curve and Pr value (>20 C/cm²) exhibit the ferroelectricity of HZO. Also, a switching current peak and polarization switching appear at identical coercive voltage (V_{c}). As illustrated in (d) of FIG. 1, the FeFET exhibits an on/off ratio of over 10⁶ and the transfer curve hardly changes even after 30 cycles of operation. Since the ferroelectricity of HZO appears when HZO has orthorhombic phase crystallinity, the crystallinity of the HZO film was analyzed through XRD analysis. As illustrated in (e) of FIG. 1, monoclinic and tetragonal phases of the HZO are major crystallinity phases of the nonannealed HZO film. After annealing at 900° C., an orthorhombic phase increased remarkably. This may represent that the ferroelectricity of the HZO film is secured by thermal stress through the annealing process.

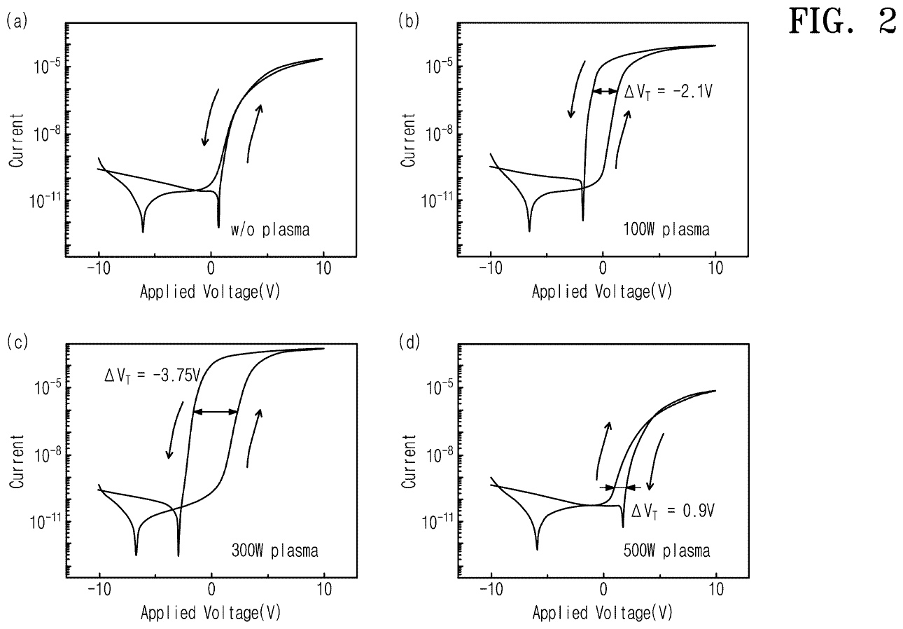

FIG. 2 illustrates I-V characteristics of FeFET devices with four different conditions of oxygen plasma treatments. Referring to (a) of FIG. 2, FeFET without plasma treatment exhibits very small threshold voltage hysteresis in a counter-clockwise direction. Referring to (b) of FIG. 2, FeFET with 100 W of plasma treatment exhibits medium hysteresis in the counter-clockwise direction. Referring to (c) of FIG. 2. FeFET with 300 W of plasma treatment exhibits the largest hysteresis in the counter-clockwise direction and has the best electrical characteristics. Referring to (d) of FIG. 2. FeFET with 500 W of plasma treatment exhibits the worst electrical characteristics and hysteresis in a clockwise direction.

With the confirmed ferroelectricity of an HZO layer, electrical characteristics of Si/HZO/HfO₂/IGZO structure-based FeFET were determined by measuring drain current along a gate voltage sweep. If only ferroelectricity is considered in a device operation, a threshold voltage shifts in a negative direction after forward sweep of a gate voltage due to a polarization phenomenon and the threshold voltage shifts in a positive direction after backward sweep, resulting in a counter-clockwise hysteresis phenomenon. However, as illustrated in (a) of FIG. 2, although the ferroelectricity of the HZO ferroelectric layer was confirmed by the P-V curve and XRD measurements, the fabricated FeFET exhibits nearly zero hysteresis and high SS. This result indicates another factor that induces the threshold voltage to shift in the opposite direction, that is, presence of an interface trap. The interface trap is present at the interface of each layer due to various causes, such as defects, dislocations, and mismatches. When the gate voltage is applied during an operation of the device, electrons in a channel layer are attracted in the direction of the gate. The attracted electrons are captured in the interface trap, which causes a shift in a direction opposite to the threshold voltage shift by polarization. Accordingly, a clockwise hysteresis phenomenon occurs. Therefore, since a deterioration in the ferroelectricity is caused by the interface trap, a decrease in the interface trap density is required.

To reduce the interface trap density, oxygen plasma treatment having high compatibility with a CMOS manufacturing process was performed for a variety of radio frequency (RF) power from 100 to 500 W. Here, the duration of plasma treatment was fixed at 60 s. During the plasma treatment, oxygen molecules are decomposed to form oxygen radicals and the formed oxygen radicals react with the interface trap. As illustrated in (b) of FIG. 2, counter-clockwise hysteresis caused by polarization switching in the ferroelectric layer was observed, and an SS value was reduced after plasma treatment at 100 W. For the plasma-treated FeFET at RF power of 300 W, counter-clockwise hysteresis and SS were further enhanced, and on-state current significantly increased compared to the FeFET without plasma treatment (see (c) of FIG. 2). However, when the RF power of the plasma treatment increased to 500 W, a direction of hysteresis was reversed to become clockwise, and the SS and on-state current deteriorated even more than those of the FeFET without plasma treatment (see (d) of FIG. 2). This was because the RF power of the plasma treatment was excessively high and the oxygen radicals broke metal-oxygen (M-O) bonds to form oxygen vacancies rather than combination with oxygen vacancies. Therefore, oxygen plasma treatment was optimized to RF power of 300 W, and counter-clockwise hysteresis was enhanced from 0.1 to −3.75 V, the SS value was reduced from 0.65 to 0.23 V/decade, and the on/off current ratio increased from 4.15×10⁶ to 2.37×10⁵. This indicates that the density of oxygen vacancy was reduced after the optimized oxygen plasma treatment.

### 2. Analysis of Effect of Oxygen Plasma Treatment

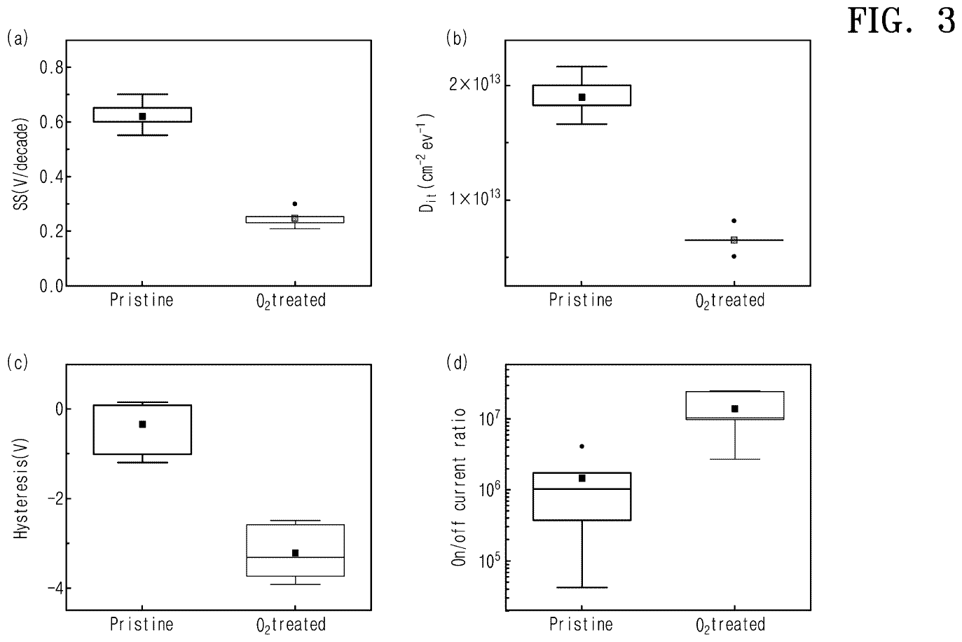

FIG. 3 illustrates box plot of electrical characteristics of data extracted from transfer curve of FeFET devices. In FIG. 3, (a) represents SS, (b) represents interface trap density, (c) represents hysteresis of threshold voltage, and (d) represents an on/off current ratio. A small square represents a mean value and a horizontal line crossing the box represents a median value.

As a result of investigating electrical characteristics of a variety of RF power of oxygen plasma treatment, the optimal RF power is 300 W. To confirm the effect of oxygen plasma treatment, electrical characteristics of FeFETs before and after performing plasma treatment need to be analyzed. Therefore, the electrical characteristics, including the threshold voltage hysteresis, the SS, the on/off current ratio, and the interface trap density (Dᵢₜ), were analyzed for five FeFETs with and without plasma treatment. First, the effect of oxygen plasma treatment on the SS was investigated. An apparent transition of the mean value after the plasma treatment decreasing from 0.62 to 0.248 V/decade was observed, indicating a decrease of ˜60%. Also, the range of variation was smaller for the FeFET with plasma treatment (see (a) of FIG. 3). A clear decrease in the SS value was observed, indicating the calibrated transfer curve on a linear scale. In sequence, since Dᵢₜ has a strong relationship with the SS value, Dᵢₜ was analyzed. That is, the higher Dᵢₜ, the more channel electrons are captured in the trap, increasing the SS. As illustrated in (b) of FIG. 3, Dᵢₜ is calculated using the measured SS value and Equation 1. In Equation 1, k denotes a Boltzmann constant, T denotes an absolute temperature, q denotes an elementary electric charge, Dᵢₜ denotes density of interface trap, and C_{g} denotes capacitance of gate dielectric. Similar to the SS value, the mean value of Dᵢₜ had a significant transition after plasma treatment, decreasing from 1.90×10¹³ to 6.52× 10¹² cm⁻² eV⁻¹. This indicates a decrease of ˜65.68%.

$$S S = \frac{ln ( 10 ) kT}{q} ( 1 + \frac{{q}^{2} {D}_{it}}{{C}_{g}} ) \qquad [ Equation 1 ]$$

As illustrated in (c) of FIG. 3, an amount of hysteresis was investigated for the FeFETs with and without plasma treatment. The FeFET without plasma treatment has weak counter-clockwise hysteresis with an average value of −0.38 V. In contrast, the FeFET with plasma treatment exhibits much larger counter-clockwise hysteresis with an average value of −3.22 V, indicating an increase of ˜8.47 times. The on/off current ratio is calculated based on the transfer curve of the FeFETs (see (d) of FIG. 3). The FeFET without plasma treatment has a larger range of variation and a smaller on/off current ratio than those of the FeFET with plasma treatment. The transition of the mean value was from 1.46×10⁶ to 1.42×10⁷, indicating an increase of ˜9.73 times. As illustrated in the transfer curve of FIG. 2, the off-state current exhibited no apparent change, but the on-state current significantly increased after the plasma treatment. Such enhancement of the on-state current results from an increase in carrier mobility because a decrease in the interface trap density induces the scattering effect, resulting in the enhancement of carrier mobility.

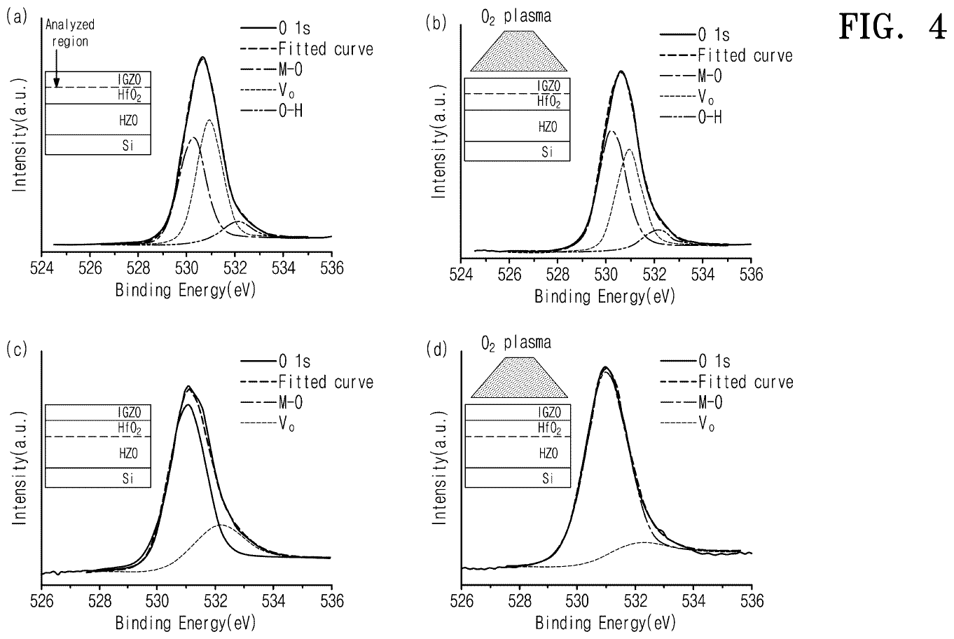

FIG. 4 illustrates deconvoluted XPS spectra of O 1s peak. (a) of FIG. 4 illustrates FeFET without plasma treatment at a channel/HfO₂ interface, (b) of FIG. 4 illustrates FeFET with plasma treatment at a channel/HfO₂ interface, (c) of FIG. 4 illustrates FeFET without plasma treatment at a HfO₂/ferroelectric layer interface, and (d) of FIG. 4 illustrates FeFET with plasma treatment at an HfO₂/ferroelectric layer interface. For the deconvoluted O 1s spectra at the channel/HfO₂ interface, red, orange, and lime green curves represent M-O bond (centered at lowest energy), Vₒ bond (centered at middle energy), and O—H bond (centered at highest energy), respectively. For the deconvoluted O 1s spectra at HfO₂/ferroelectric layer interface, red and orange curves represent M-O bond (centered at lowest energy) and Vₒ bond (centered at middle energy), respectively.

XPS depth analysis was performed for FeFETs with and without oxygen plasma treatment to investigate e presence and concentration of interface traps at the channel/HfO₂ interface and the HfO₂/ferroelectric layer interface by sputtering from the channel surface to the ferroelectric layer direction. At the channel/HfO₂ interface. O 1s spectra were analyzed using deconvolution into three peaks centered at 530.24, 530.94, and 532.14 eV based on Lorentzian-Gaussian profile. The peak centered at the lowest energy represents M-O bonds, the peak centered at the middle energy represents oxygen vacancy (Vₒ) bonds, which are main components of interface traps, and the peak centered at the highest energy represents metal-hydroxyl (O—H) bonds. For the FeFET without plasma treatment, an area ratio of M-O bonds/total was 44.496, Vₒ bonds/total was 48.273, and O—H bonds/total was 7.231 (see (a) of FIG. 4). The Vₒ bonds/total value exceeded the M-O bonds/total value, indicating that the interface trap density was significantly high at the channel/HfO₂ interface. However, after oxygen plasma treatment, the area ratio of M-O bonds increased to 53.01, Vₒ bonds/total decreased to 40.188, and O—H bonds/total was almost the same at 6.801 (see (b) of FIG. 4). This result proves that the interface trap density was significantly reduced through plasma treatment because oxygen radicals generated by plasma incorporate oxygen vacancies and passivate interface traps. Meanwhile, O 1s spectra were deconvoluted into two peaks centered at 531.14 and 532.14 eV at the HfO₂/ferroelectric layer interface. The peak centered at lower energy represents M-O bonds, and the peak centered at higher energy represents oxygen vacancy (Vₒ) bonds. Similar to analysis at the channel/HfO₂ interface, the area ratio of the M-O bonds increased from 76.821 to 93.144 after oxygen plasma treatment (see (c) and (d) of FIG. 4). More importantly, the Vₒ peak/total peak area ratio significantly decreased from 23.179 to 6.856, indicating that the interface trap density significantly decreased after oxygen plasma treatment. The analyzed electrical characteristics and XPS depth analysis of oxygen vacancies represent that oxygen plasma treatment is an effective and CMOS-compatible method for remarkably reducing the interface trap density to improve memory characteristics caused by ferroelectricity.

### 3. Threshold Voltage Hysteresis Induced by Polarization and Interface Trap

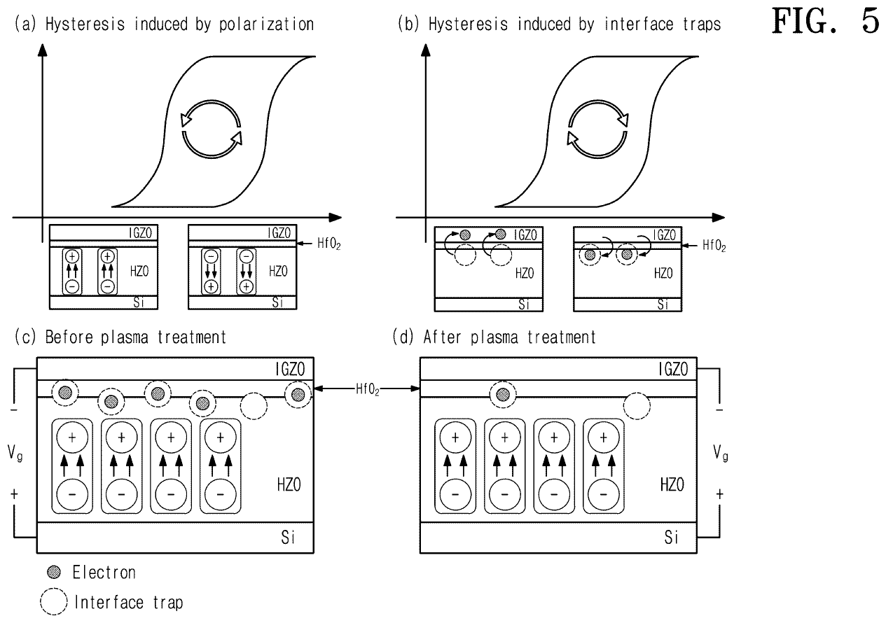

FIG. 5 illustrates an operation mechanism of fabricated FeFET. (a) of FIG. 5 illustrates counter-clockwise hysteresis induced by polarization in a ferroelectric layer, and (b) of FIG. 5 illustrates clockwise hysteresis induced by interface traps at a channel/HfO₂ interface and an HfO₂/HZO interface. (c) of FIG. 5 illustrates a cross-sectional view when a positive voltage was applied to a Si gate terminal for FeFET without oxygen plasma treatment and (d) of FIG. 5 illustrates a cross-sectional view when the positive voltage was applied to the Si gate terminal for FeFET with oxygen plasma treatment.

A study for a device operation mechanism is required through a comparative analysis of threshold voltage shift by polarization in the ferroelectric layer and trapping/de-trapping in the interface traps. The ferroelectricity of HZO occurs when HZO has an orthorhombic phase, which is formed by thermal energy, stress, doping, and the like. HZO has a monoclinic phase as deposited, but exhibits an intermediate orthorhombic phase through an annealing process and a tetragonal phase with no ferroelectricity when additional energy is applied. For the orthorhombic phase HZO, oxygen atoms inside the HZO move in a direction opposite to that of an electric field, causing polarization when an external electric field is applied by an input signal. As illustrated in (a) of FIG. 5, when a positive voltage is applied to a gate terminal, an electrical field forms in an upward direction, attracting oxygen atoms inside the HZO toward the gate. Therefore, a polarization phenomenon is caused by the attracted oxygen atoms in a direction identical to that of the electric field. Due to upward polarization, electrons, which are majority carriers of the channel, are attracted toward the ferroelectric layer, facilitating formation of the channel followed by a negative shift in a threshold voltage. Therefore, the upward polarization occurs after forward bias sweep that shifts the threshold voltage in a negative direction. On the other hand, when a negative voltage is applied to the gate terminal, oxygen atoms inside the HZO are attracted toward the channel, causing downward polarization. With the downward polarization, electrons in the channel layer are repelled toward the channel surface, causing a positive shift in the threshold voltage. Therefore, the positive shift in the threshold voltage occurs after reverse bias sweep. In contrast, interface traps present in IGZO/HfO₂ and the HfO₂/HZO layer cause clockwise threshold voltage hysteresis (see (b) of FIG. 5). When interface traps are present, electrons in the channel layer may be trapped or de-trapped along the applied gate voltage due to the electric field. When a positive gate voltage is applied, channel electrons are attracted toward the gate and may be trapped in the interface traps. Trapped electrons disturb formation of a channel through Coulomb force, causing the positive shift in the threshold voltage after forward bias sweep. Conversely, when a negative gate voltage is applied, the trapped electrons are de-trapped from the interface traps, resulting in a negative shift in the threshold voltage after reverse bias sweep. Therefore, since the polarization and the interface traps shift the threshold voltage in opposite directions, small hysteresis of the FeFET without the plasma treatment may be explained. As illustrated in (c) and (d) of FIG. 5, polarization is not affected by plasma treatment since plasma treatment does not change a crystalline phase of HZO, but the interface trap density is remarkably induced with plasma treatment. Therefore, enlarged hysteresis of the FeFET with plasma treatment may be explained by the induced interface trap density. With the oxygen plasma treatment, enhanced synaptic characteristics may be expected since precise control of the threshold voltage is enabled by reducing the interface trap density.

4. Synaptic Characteristics by Polarization and Enhancement with Oxygen Plasma Treatment

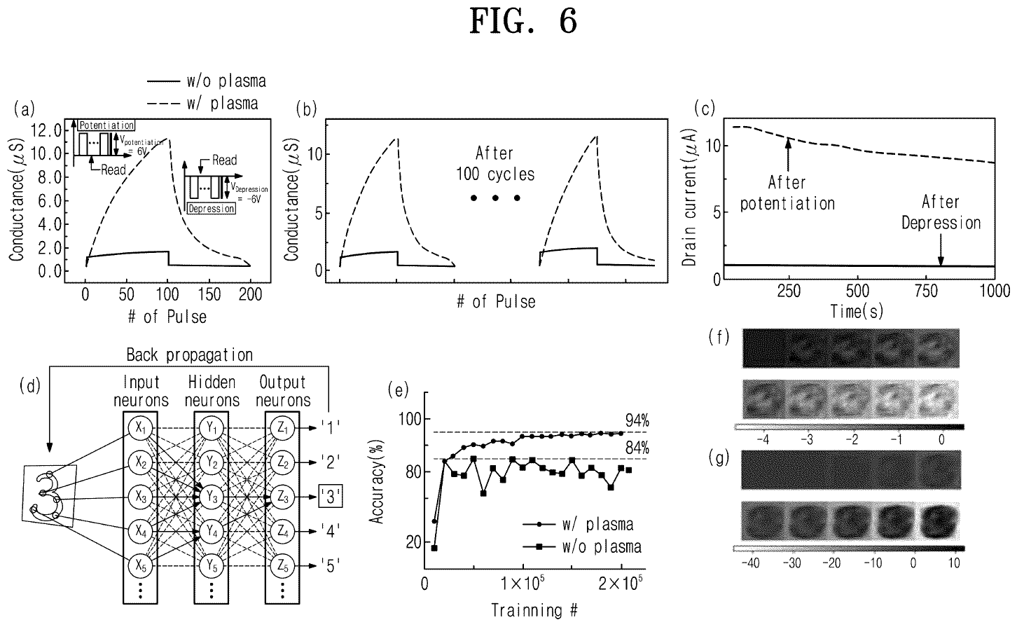

FIG. 6 illustrates measured synaptic plasticity of a FeFET-based artificial synaptic device. (a) of FIG. 6 illustrates potentiation and depression curve implemented using 100 presynaptic pulses for each. (b) of FIG. 6 illustrates variation in synaptic plasticity when numerous potentiation and depression cycles are repeated. (c) of FIG. 6 illustrates retention characteristics after potentiation and depression when only a drain voltage is applied. (d) of FIG. 6 illustrates a structure of an artificial neural network having two layers. (e) of FIG. 6 illustrates operation accuracy of simulated pattern recognition using MNIST data with synaptic characteristics. (f) of FIG. 6 illustrates a visualized synaptic weight map along the number of training epochs when using synaptic characteristics of a FeFET with plasma treatment and (g) of FIG. 6 illustrates a visualized synaptic weight map along the number of training epochs when using synaptic characteristics of a FeFET without plasma treatment.

Since a FeFET device may control channel conductance by adjusting the threshold voltage along an input voltage signal, synaptic plasticity is emulated by modulating an amount and a direction of polarization in a ferroelectric layer using a gate as a presynaptic input terminal and by using a source/drain as a post-synaptic output terminal. When a positive voltage pulse is applied to a gate terminal, polarization occurs toward a channel direction. Therefore, the channel conductance increases due to attracted channel electrons, which is called potentiation. Conversely, when a negative voltage pulse is applied, polarization occurs toward the gate, causing a decrease in the channel conductance, which is called depression.

To investigate synaptic characteristics, a pulse train including 100 identical positive pulses for potentiation and 100 identical negative voltage pulses for depression was applied while maintaining the drain voltage at −1 V for a read operation (see (a) of FIG. 6). Therefore, synaptic plasticity may be implemented with symmetric potentiation and depression and synaptic characteristics including a max/min weight ratio, linearity of weight update, and the number of weights. Based on a polarization-switching mechanism, the number, amplitude, and width of input pulses may be modified to optimize characteristics of synaptic plasticity. The pulse width is optimized to 0.5 ms, and the pulse amplitude is optimized to 6 V (for potentiation) and −6 V (for depression). Also, the optimized condition of the input pulse demonstrates the feasibility of low power and high speed operation, which is an essential property of a neuromorphic computing system due to its low amplitude and duration. The power consumption of proposed FeFET-based artificial synapse was calculated to be 4.35 pJ. (power consumption=(pulse width)×(pulse amplitude)×(gate leakage current)=(0.5 ms)×(6 V)×(1.45 nA)=(4.35 pJ))

Similar to the previously investigated enhancement of electrical characteristics by plasma treatment, oxygen plasma treatment is remarkably effective in improving synaptic characteristics. As illustrated in (a) of FIG. 6, the max/min weight ratio increased over seven times after the oxygen plasma treatment. The increase in the max/min weight ratio results from an increase in on-state current in transfer curve (see FIG. 2). Since sensing margin may increase due to an increased interval between weights, the increased max/min weight ratio may enhance the accuracy of a neuromorphic system. With respect to the linearity of the weight update and the number of weights, an abrupt transition of synaptic weight appears after few input pulses, and is saturated within 10 input pulses for the FeFET without plasma treatment. In contrast, for the plasma-treated FeFET, potentiation and depression curves exhibit continuous and linear weight update along 100 input pulses, indicating that the number of weights of the FeFET with plasma treatment is 100. Also, the linearity of weight update exhibits an apparent improvement after oxygen plasma treatment. The linearity is enhanced from 15.677 to 1.153 (for potentiation) and from −16.649 to −0.125 (for depression). When the weight update is perfectly linear, an absolute value of linearity is 1. When interface traps are present at high concentration, channel electrons are trapped or de-trapped during a device operation. Since electron trapping and electron de-trapping induce weight update in a direction opposite to that of weight update by polarization, the weight update that occurs along a change in an amount and a direction of polarization according to the number of input pulses is disturbed. Therefore, by reducing the interface trap density through oxygen plasma treatment, the channel conductance may be precisely controlled with the input signal without disturbance, and synaptic characteristics may be significantly improved.

Although outstanding synaptic characteristics are achieved in the proposed artificial synaptic device, several additional properties need to be verified to perform a role of artificial synapses in a high-accuracy neuromorphic system. First, the artificial synaptic device needs to endure numerous input signals to perform a role of a processor. To test its capability as the processor, more than 100 cycles of input pulses were applied to the fabricated FeFET-based artificial synaptic device. As illustrated in (b) of FIG. 6, the potentiation and depression curves did not have a significant difference in conductance variation, even after more than 2×10⁵ input pulses, indicating that repeatability was verified. Also, the artificial synaptic device needs to maintain its weight after applying input signals to perform a role of a memory. As illustrated in (c) of FIG. 6, a synaptic weight occurring as channel conductance was almost maintained after potentiation and depression for 1000 s when only a read voltage was applied. No considerable transition in conductance was observed, indicating that the synaptic plasticity of the FeFET-based artificial synaptic device is long-term plasticity, which is essential for a memory operation of a human brain emulating artificial synaptic device.

To investigate the effect of oxygen plasma treatment on FeFET-based artificial synapses, an artificial neural network (ANN) was organized with two layers based on the measured synaptic characteristics (see (d) of FIG. 6). Synapses in the ANN connect 784 input neurons, 100 neurons in layer 1, and 10 neurons in layer 2 while adjusting and storing weights. With the ANN, a pattern recognition simulation was performed using MNIST data. As illustrated in (e) of FIG. 6, the pattern recognition accuracy was 84% for the FeFET without plasma treatment, and the FeFET with plasma treatment exhibited a 10% improvement as pattern recognition accuracy of 94%. Also, the fluctuation in accuracy with an increase in epochs was more severe for the FeFET without plasma treatment. Subsequently, a weight map obtained from accuracy simulation was plotted after the pattern recognition simulation. As illustrated in (f) and (g) of FIG. 6, the shape of number 3 was clearer for the FeFET with plasma treatment, and the range of synaptic weights in a color scale bar was also smaller. A small range of synaptic weights represents higher accuracy since a weight of each pixel does not change rapidly. Therefore, it is suitable to properly adjust a weight according to an input.

In most previous studies, as shown in Table 1, synaptic plasticity was implemented with voltage pulses of progressively incremental amplitude or width along the pulse number to enhance synaptic characteristics. However, the implementation of synaptic plasticity with the incremental amplitude or width of presynaptic signals allows synaptic characteristics, such as linearity, a max/min weight ratio, and the number of states, to be controlled. Such synaptic characteristics may be controlled by adjusting an amplitude interval of input pulses. In contrast, the proposed FeFET-based artificial synaptic device has outstanding synaptic characteristics with spike number-dependent plasticity (SNDP), which is implemented only by input voltage pulses of constant amplitude and width through oxygen plasma treatment. Also, spike amplitude dependent plasticity (SADP) in which a weight varies according to the amplitude of presynaptic signals and spike duration dependent plasticity (SDDP) in which a weight varies according to the width of presynaptic signals are implemented. Finally, Table 1 shows comparison results for synaptic characteristics, including symmetry, linearity, the number of weights, a max/min weight ratio, and a scheme of input pulse.

TABLE 1

| | | | # of | Max/min | |
|---|---|---|---|---|---|
| Structure | Symmetricity | Linearity | weights | weight ratio | Pulse scheme |
| HZO/HfO₂/IGZO | ◯ | 1.153/−0.125 | 100 | 25.74 | Identical |
| HZO/Al₂O₃/Si | X | 6.77/−4.84 | 16 | >10 | Identical |
| HZO/Al₂O₃/Si | ◯ | 1.74/1.23 | 16 | >10 | Incremental |
| HZO/IZTO | ◯ | −0.4/−0.3 | 64 | 140.2 | Incremental |
| HZO/IGZO | X | — | 10 | 1.05 | Light |
| HZO/SiO₂/Si | X | — | 50 | >10 | Identical |
| P(VDF-TrFE)/MoS₂ | X | — | 100 | 85.71 | Identical |
| P(VDF-TrFE)/MoS₂ | ◯ | 2.02/3.42 | 128 | 8.97 | Identical |
| α-In2Se3/GaSe | X | <4 | 100 | >1.5 | Identical |

The device described above can be implemented as hardware elements, software elements, and/or a combination of hardware elements and software elements. For example, the device and elements described with reference to the embodiments above can be implemented by using one or more general-purpose computer or designated computer, examples of which include a processor, a controller, an ALU (arithmetic logic unit), a digital signal processor, a microcomputer, an FPGA (field programmable gate array), a PLU (programmable logic unit), a microprocessor, and any other device capable of executing and responding to instructions. A processing device can be used to execute an operating system (OS) and one or more software applications that operate on the said operating system. Also, the processing device can access, store, manipulate, process, and generate data in response to the execution of software. Although there are instances in which the description refers to a single processing device for the sake of easier understanding, it should be obvious to the person having ordinary skill in the relevant field of art that the processing device can include a multiple number of processing elements and/or multiple types of processing elements. In certain examples, a processing device can include a multiple number of processors or a single processor and a controller. Other processing configurations are also possible, such as parallel processors and the like.

The software can include a computer program, code, instructions, or a combination of one or more of the above and can configure a processing device or instruct a processing device in an independent or collective manner. The software and/or data can be tangibly embodied permanently or temporarily as a certain type of machine, component, physical equipment, virtual equipment, computer storage medium or device, or a transmitted signal wave, to be interpreted by a processing device or to provide instructions or data to a processing device. The software can be distributed over a computer system that is connected via a network, to be stored or executed in a distributed manner. The software and data can be stored in one or more computer-readable recorded medium.

A method according to an embodiment of the invention can be implemented in the form of program instructions that may be performed using various computer means and can be recorded in a computer-readable medium. Such a computer-readable medium can include program instructions, data files, data structures, etc., alone or in combination. The program instructions recorded on the medium can be designed and configured specifically for the present invention or can be a type of medium known to and used by the skilled person in the field of computer software. Examples of a computer-readable medium may include magnetic media such as hard disks, floppy disks, magnetic tapes, etc., optical media such as CD-ROM's, DVD's, etc., magneto-optical media such as floptical disks, etc., and hardware devices such as ROM, RAM, flash memory, etc., specially designed to store and execute program instructions. Examples of the program instructions may include not only machine language codes produced by a compiler but also high-level language codes that can be executed by a computer through the use of an interpreter, etc. The hardware mentioned above can be made to operate as one or more software modules that perform the actions of the embodiments of the invention and vice versa.

While the present invention is described above referencing a limited number of embodiments and drawings, those having ordinary skill in the relevant field of art would understand that various modifications and alterations can be derived from the descriptions set forth above. For example, similarly adequate results can be achieved even if the techniques described above are performed in an order different from that disclosed, and/or if the elements of the system, structure, device, circuit, etc., are coupled or combined in a form different from that disclosed or are replaced or substituted by other elements or equivalents. Therefore, various other implementations, various other embodiments, and equivalents of the invention disclosed in the claims are encompassed by the scope of claims set forth below.

What is claimed is:

1. A ferroelectric-based semiconductor device comprising:
a substrate used as a gate;
a gate oxide film formed on the substrate;
a channel formed on the gate oxide film; and
a source/drain formed on the channel,
wherein the semiconductor device is plasma-treated.

2. The ferroelectric-based semiconductor device of claim 1, wherein the substrate is a p-type silicon wafer.

3. The ferroelectric-based semiconductor device of claim 2, wherein the gate oxide film includes a ferroelectric material.

4. The ferroelectric-based semiconductor device of claim 3, wherein the ferroelectric material includes at least one of A₁:HfO₂, zirconium oxide and hafnium oxide (HfZrO), InSe, and CIPS.

5. The ferroelectric-based semiconductor device of claim 4, wherein the channel is indium gallium zinc oxide (IGZO).

6. The ferroelectric-based semiconductor device of claim 5, further comprising:
a dielectric layer between the gate oxide film and the channel,
wherein the dielectric layer includes HfO₂.

7. The ferroelectric-based semiconductor device of claim 6, wherein the semiconductor device is oxygen plasma-treated at radio frequency (RF) power of 300 W.

8. The ferroelectric-based semiconductor device of claim 7, wherein the semiconductor device is one of a memory device, a field effect transistor (FET), and an artificial synaptic device.

9. A method of manufacturing a ferroelectric-based semiconductor device, the method comprising:
preparing a substrate;
depositing a gate oxide film on the substrate;
forming a channel on the gate oxide film;
forming a source/drain on the channel; and
plasma-treating the semiconductor device.

10. The method of claim 9, wherein the substrate is a p-type silicon wafer,
the gate oxide film includes a ferroelectric, and
the ferroelectric material includes at least one of A₁:HfO₂, zirconium oxide and hafnium oxide (HfZrO), InSe, and CIPS.
